(19) United States
(12) Patent Application Publication
(10) Pub. No.: US 2010/0231386 A1
(43) Pub. Date: Sep. 16, 2010

(54) SOLAR-POWERED SENSING

(75) Inventor: William J. Barnes, Miami, FL (US)

Correspondence Address: FISH & RICHARDSON PC, P.O. BOX 1022, MINNEAPOLIS, MN, 55440-1022, US

(73) Assignee: Lumen International, Inc., Miami, FL (US)

(21) Appl. No.: 12/403,604

(22) Filed: Mar. 13, 2009

(51) Int. Cl. G08B 13/00; H01L 31/00

(52) U.S. Cl. 340/541; 136/252; 136/256

(57) ABSTRACT

A solar cell generates electricity, a housing for the solar cell and/or sensor is configured to suit an environment in which the housing is to be deployed so that a person who is in the environment and in eye contact with the housing is unaware that the housing is associated with a solar cell and/or sensor. A port couples the generated electricity to a device that senses human activity in the vicinity of the apparatus.

### BACKGROUND

This description relates to solar-powered sensing.

Solar-powered sensors, for example, can be deployed covertly to achieve persistent surveillance. Such solar-powered sensors typically have been deployed by air drops or by hand and are used to monitor roads, trails, rivers, and airfields. Deployment can also be done by artillery shells (filled with sensors), autonomous underwater vehicles, UAVs, and other innovative devices to “seed” an area to monitor activities, for example, illicit activities.

These sensors tend to have shapes that are not natural to the environment and therefore can easily be identified as abnormal or unnatural, even if painted with camouflage patterns.

The useful life of such a device can be extended using long-endurance batteries and by reducing the power consumption of components.

Information collected by the sensors can be reported back using a larger number of transmissions at very low power or smaller number of transmissions at high power, as limited by their finite battery life.

Covert sensor arrays, such as the DARPA Covert Long-Endurance Nano-Sensor (CLENS) can detect, track, and analyze passing targets.

### SUMMARY

In general, in an aspect, a solar cell generates electricity, a housing for the solar cell is configured to suit an environment in which the housing is to be deployed so that a person who is in the environment and in eye contact with the housing is unaware that the housing is associated with a solar cell. A port couples the generated electricity to a device that senses human activity in the vicinity of the apparatus.

Implementations may include one or more of the following features. The housing is configured to have the appearance of plant material in the environment. The housing is configured to have the appearance of a leaf. The housing is configured to have the appearance of a plant. The housing is configured to have the appearance of man-made material in the environment. The housing is configured to have the appearance of trash. The housing is configured to have the appearance of a discarded bottle or can. The solar cell comprises a thin-film cell. The solar cell comprises a photovoltaic cell. The solar cell comprises a flexible cell. The housing is configured to have the appearance of wood. The apparatus of claim one in which the housing comprises wood. The wood comprises a portion of a structure. The housing comprises wood. The solar cell is camouflaged.

In general, in an aspect, a set of power units each comprises a solar cell. Each of the solar cells is attached to a housing. Each of the housings is configured to have an appearance of an environment in which the housing is to be deployed. A set of sensors is powered by the solar cells. At least one relay device is to be deployed at a distance from the solar cells. The relay device is powered by one or more of the solar cells and has a relay housing configured to have an appearance of the environment in which the relay housing is to be deployed. The relay device has wireless communication capability to communicate with the sensors and to communicate with a remote data collection device.

Implementations may include one or more of the following features. Each of the power unit housings is configured to have an appearance of plant material. Each of the power unit housings is configured to have the appearance of a leaf. Each of the solar cells comprises a thin-film solar cell.

In general, in an aspect, a surveillance system comprises solar cells camouflaged as artificial plant material. Camouflaged sensors are powered by the solar cells. Wireless communication facilities send surveillance information determined by the camouflaged sensors to a remote data collector.

In general, in an aspect, a surveillance system comprises solar cells camouflaged as elements of a construction site. Camouflaged sensors are powered by the solar cells to detect unauthorized human activity in the vicinity of the construction site. A wireless communication facility is configured to send an alert when unauthorized human activity is sensed.

In general, in an aspect, a device collects solar energy covertly by being camouflaged relative to the context in which it is deployed. In some implementations, the camouflaging is relative to a context of at least one of: plant material, mountains, desert, ice, snow, rocks, sand, mud, bricks, signs, banners, construction material, roof material, or an urban landscape.

These and other aspects and features, and combinations of them, may be expressed as methods, systems, means for performing functions, software products, business methods, and in other ways.

Other aspects, features, and advantages will be apparent from the following description and claims.

### DESCRIPTION

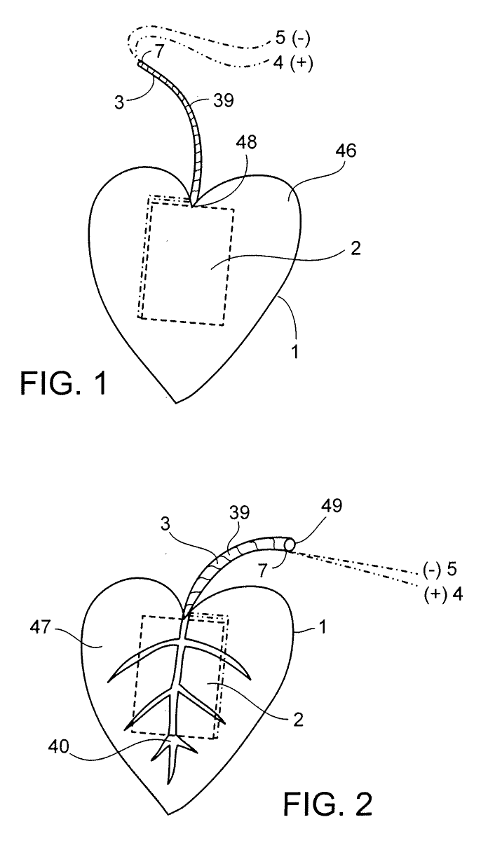

FIG. 1 is a top view of an artificial leaf.

FIG. 2 is a bottom view of an artificial leaf.

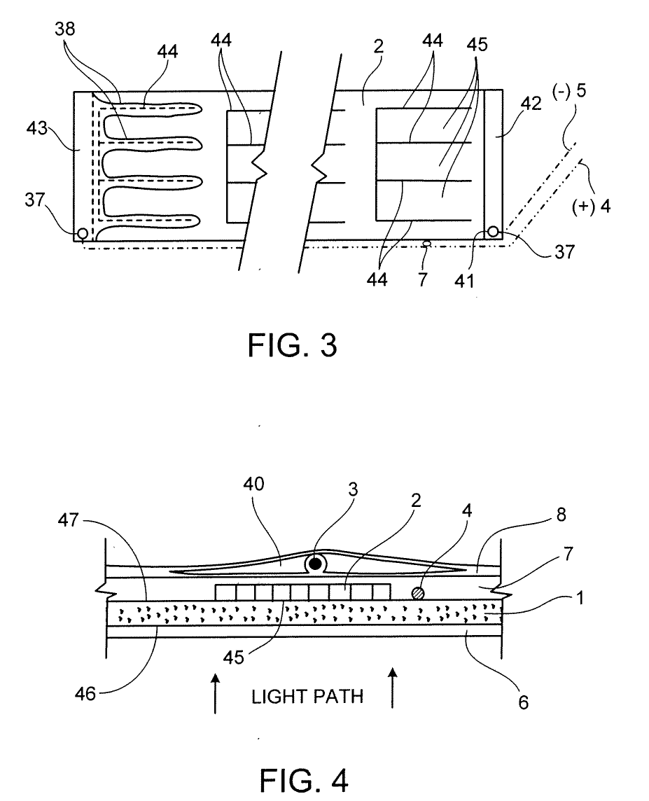

FIG. 3 is a top view of the solar cell.

FIG. 4 is a section through an artificial leaf.

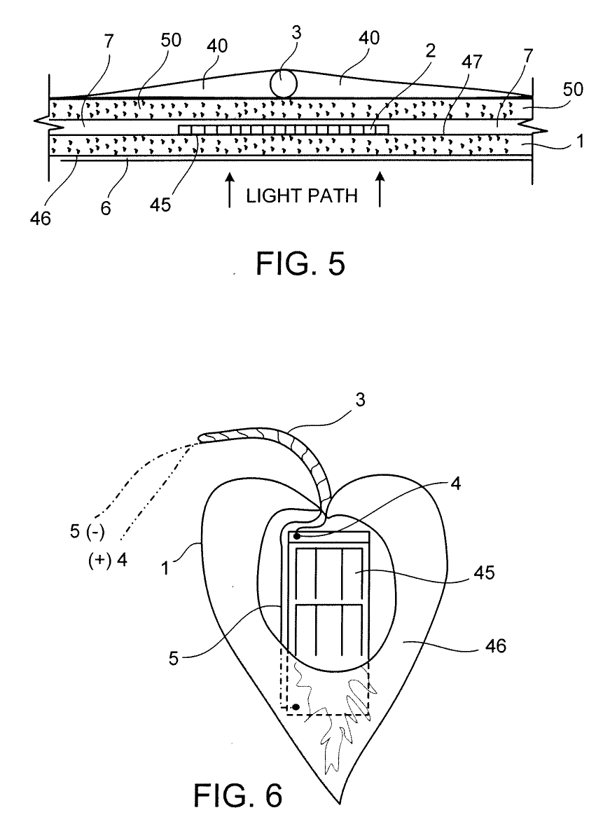

FIG. 5 is a section through an artificial leaf.

FIG. 6 is a top view of an artificial leaf partly broken away.

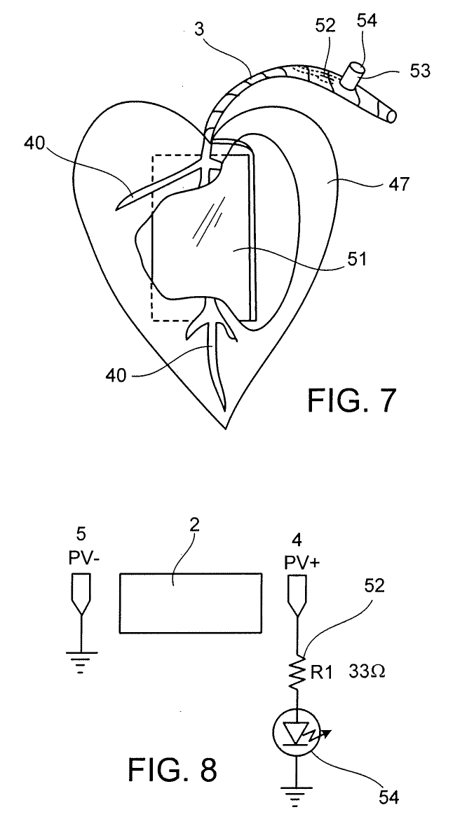

FIG. 7 is a bottom view of an artificial leaf partly broken away.

FIG. 8 is a circuit diagram.

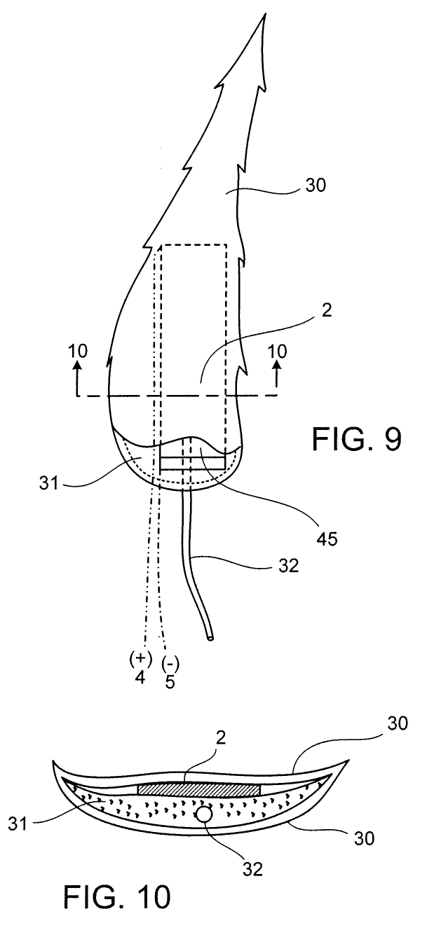

FIG. 9 is a top view of an artificial leaf.

FIG. 10 is a cross-section of an artificial leaf.

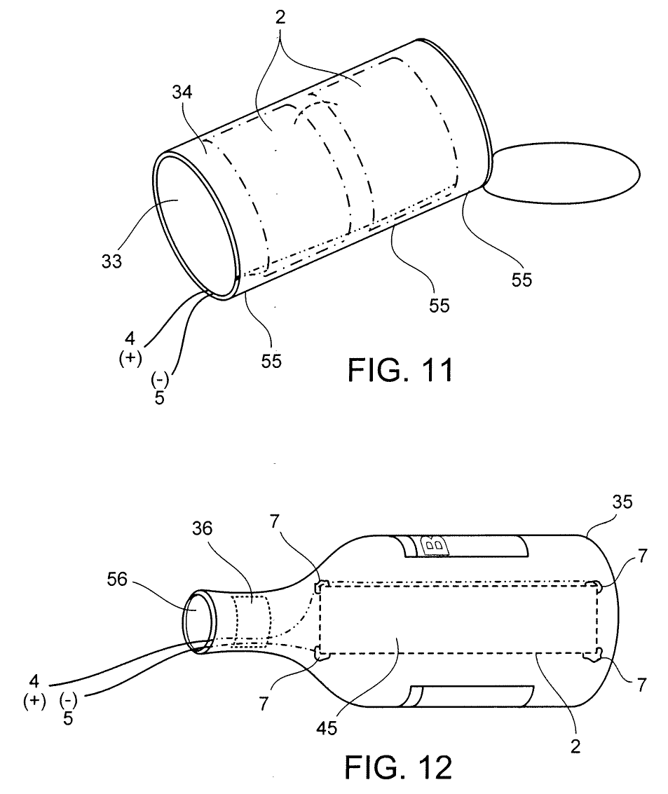

FIG. 11 is a perspective view of a tin can.

FIG. 12 is a perspective view of a beer bottle.

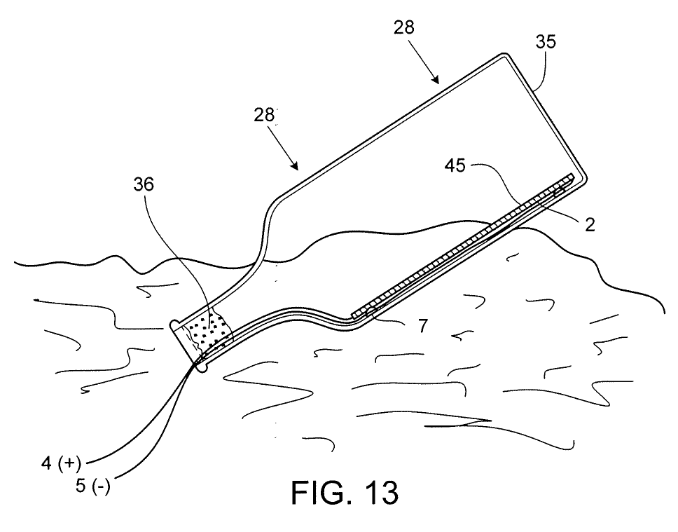

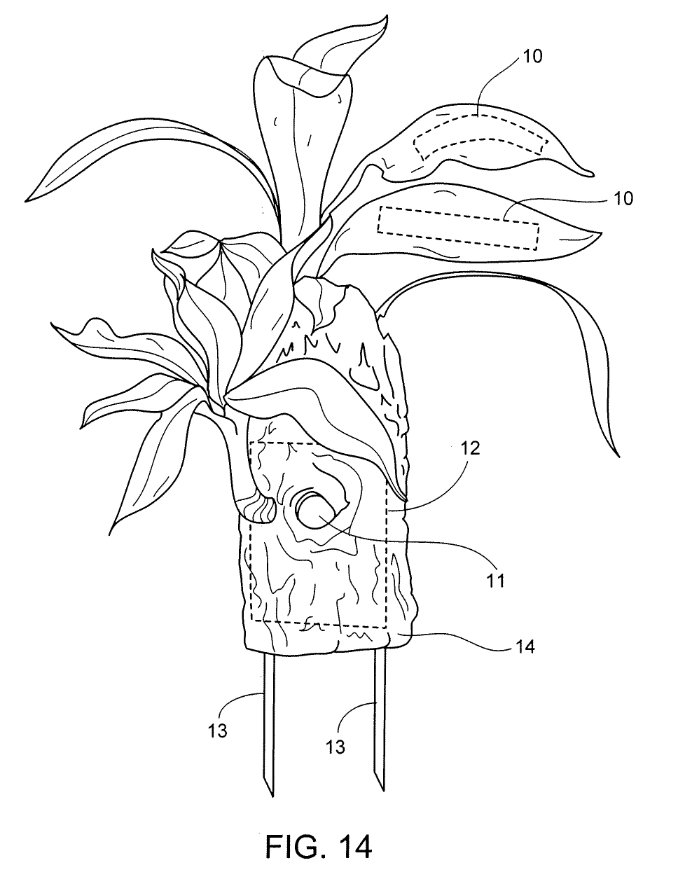

FIG. 13 is a schematic view of a deployment of a sensor.

FIG. 14 is a schematic view of a camouflaged sensor.

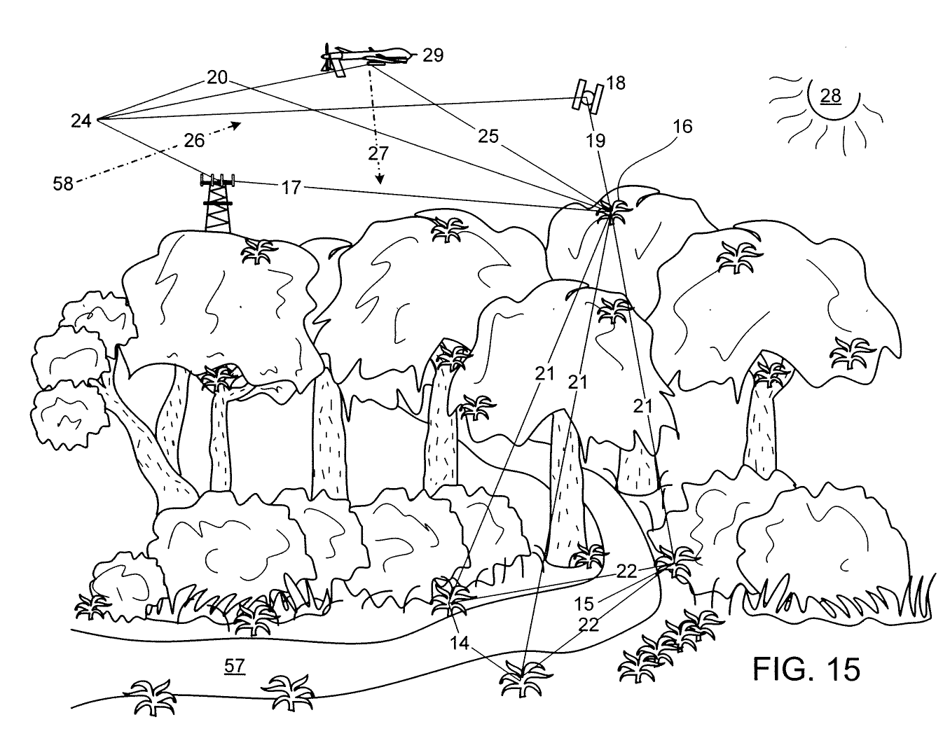

FIG. 15 is a perspective view of a rain forest.

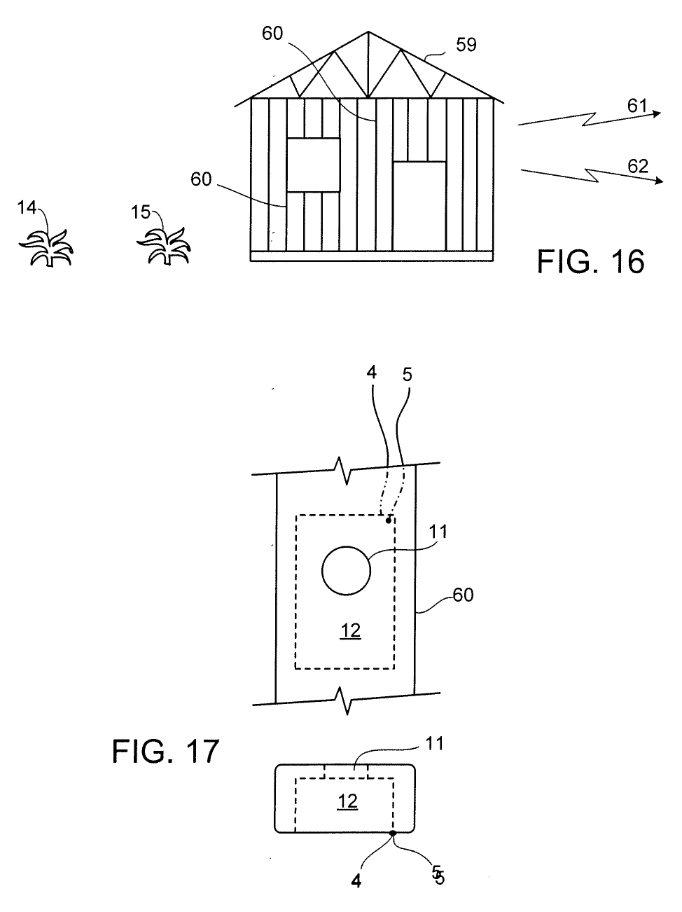

FIG. 16 is a side view of a house under construction.

FIG. 17 is a top and sectional view of a board.

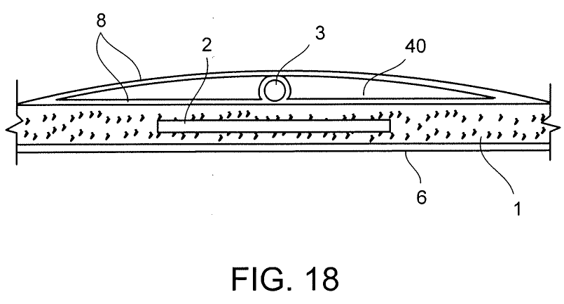

FIG. 18 is a sectional view of an artificial leaf.

Here we describe examples of devices that incorporate solar cells in objects that are configured not to be perceived as solar power containing devices in the context in which they are deployed, in other words, they are camouflaged.

Among the advantages of these and other examples are that a person can look directly at such a device, yet not recognize it as a “threat.” The inclusion in a camouflaged device of a covert solar collection capability allows for daily replenishment of battery-powered components, such as tracking and other sensors, through a trickle-charge/recharge from solar cells, for example. This enhancement to the typical power limitation allows for an increased number of duty cycles, higher power outputs, and a greatly extended sensor lifetime, as compared to a battery-only design. The ability to provide long-term power should spur new advancements in sensor array designs. With solar-power replenishment available, sensors can be employed that have active RF communication systems, which can provide near real-time monitoring of remote locations through a host of relay signal options. SAT-phone and cell phone options are possible in spite of their relatively high power consumption, and a solar-powered relay system can maintain a listening watch for downlink signals to activate specific sensors, cameras, or other devices in direct response to detected activities, such as enemy or troop movement.

An example construction of a solar-powered sensor is shown in FIGS. 1 through 3.

In FIG. 1, an example artificial leaf 1 made of silk or plastic is the framework for a solar cell 2. The leaf 1 in this example is thin enough to allow natural light (for example, sunlight whether direct or filtered) to pass through its body to be collected by the solar cell 2.

Artificial leaves that include white patterns will allow more natural light into the solar cell than will leaves of solid green, thereby providing higher efficiency. Lighter color green is more efficient than dark green, but the leaf type, shape, size, and color are chosen to blend with a natural environment where the leaf will be employed.

In some examples, the leaf can be formed by die cutting a sheet of plastic or silk that is between about 0.5 mm and about 2.0 mm thick. In other cases, the solar cell 2 is incorporated into an existing artificial leaf. Flexible, thin-film photovoltaic solar cells 2 have advantages over other types of solar cells. Thin-film solar cells 2 are durable, light weight, thin, flexible, and weather resistant, which makes them useful for a camouflaged solar cell collection system. Thin-film solar cells come in various sizes and shapes, and almost any size may be incorporated, depending upon power requirements and camouflage design. In individual leaves, good success was obtained using an MP3-25 cell marketed by PowerFilm, Inc. of Ames, Iowa 50014. This cell has an open-circuit Voltage (Voc) of 4.1 volts and a rated voltage of 3.0 volts at 25 milli-amps. Each cell is 114 mm (3.9 in) by 25 mm (1 in) and is 0.2 mm thick with a weight of 0.8 grams (0.03 oz). The solar cell 2 and its two electrical leads 4 and 5 are attached to the leaf body 1 (with the solar collector face of the solar cell 45 facing upward toward the sun when deployed).

In some examples, the leads 4 and 5 are 24 to 30-gauge stranded wire wrapped around a stem 3 of the artificial leaf and having sufficient length (for example, 2-3 feet of wire leads) to reach the component (not shown) they will power. The artificial stem 3 can be wire a coated with plastic to provide a realistic shape and color. The wire center of the stem continues up along the base of the leaf 2 to form the supporting structure for leaf ribs 40 which are also made of molded plastic and are part of the stem assembly. The leaf ribs 40 are attached to the silk or plastic leaf blank 1 by adhesive or by molding as a part of the leaf blank. The stem 3 and ribs 40 can be the same color as the leaf, or a different color, to match the type of natural plant they are representing. After the leads 4 and 5 are wrapped around the artificial leaf stem 3, they are secured in place using a small amount of self-leveling adhesive 7. The stem 3 is then wrapped with florist's tape 39 and sealed using a coating of pigmented flexible adhesive sealant 8 to seal and secure the leads in place.

The top face of the leaf 46 is covered by a clear ultra-violet protective coating 6 to prevent the breakdown of the leaf in prolonged exposure to sunlight. A commercially available example of this UV coating is called Clear Shield, manufactured by ClearStar, Inc. which is applied in a 0.2 to 0.5 mm coating. This coating is available in clear, semi-gloss, and matte finishes and may be painted or sprayed onto the leaf. Other typical examples of chemical compounds that have suitable UV protection characteristics are hydroxyphenyl-benzotriazol, benzophenon and hydroxyphenyl-triazine.

FIG. 2 shows a bottom view of the leaf 1 with the attached solar cell 2. The solar cell is not visible from the bottom of the leaf, but is covered to provide concealment and for the protection of the cell and leads.

Two good ways to mate the solar cell 2 to the leaf 1 are shown in FIGS. 4 and 5. In these examples, the semi-rigid stem 3 and ribs 40 are attached to the bottom of an artificial leaf to provide support and a realistic visible appearance (or “signature”). The ribs 40 are made of molded plastic and are fused with the stem 3. The purpose of the stem 3 and ribs 40 is the same as in normal leaves: to support the leaf so that it may collect energy from the sun. Depending upon the type of leaf being represented or imitated, the ribs 40 may be the same color as the leaf, or a slightly different color, usually darker. The ribs 40 and stem 3 are held to the bottom face of the leaf 47 and to the back side of the solar cell 2 by a self-leveling adhesive 7 and coated by a pigmented flexible sealant 8 to form a realistic unit. (See FIGS. 4 and 5 for details of the application of the self-leveling adhesive 7 and pigmented flexible sealant 8.)

The solar cell 2 is located between the bottom face of the leaf 47 and the stem 3 and ribs 40 with the solar collector side of the solar cell 45 facing the top face of the leaf 46. Another layer of pigmented flexible sealant 8 is painted over the entire bottom of the leaf 47 and the ribs 40, to seal the unit and smooth out any visible straight edges of the solar cell 2. The leads 4 and 5 extending out from the base of the stem 49 are secured with a drop of self-leveling adhesive 7, then the stem 3 is wrapped with florist's tape 39 and sealed with a coating of pigmented flexible sealant 8.

Prior to mating to the artificial leaf 1, the solar cell 2 is modified to reduce its visibility (signature) from the front through the leaf material. As shown in FIG. 3, to achieve this, the metallic contact strips 42 and 43 under the solar cell's sealed coating 41 are exposed at the solder points 37. The sealed coating of the cell 41 covers the solar cell 2 completely and is scraped off to form the two solder points 37 to expose the bare metal of the contact strips 42 and 43 to allow soldering of the leads 4 and 5 to the solar cell 2. The negative lead (cathode) 5 is soldered to the end of the solar cell 2 at the negative contact strip 42, and the positive lead (anode) 4 is soldered to the end of the solar cell 2 at the positive contact strip 43. Then the electrical connections at the solder points 37 are verified, and the voltage of the solar cell is read on a voltmeter with the cell in an area of known illumination that should provide a specific voltage.

For example, In a 10,000 ft.-candle lighted area, the cell should produce an open circuit DC voltage ranging from a maximum of 4.2 volts DC (VDC) to a minimum of 3.8 VDC with a typical short-out amperage of about 35 milliamps with a representative test load on the circuit. Cells that do not produce the stated minimums in the calibrated light test are rejected.

After the cell has passed the voltage test and the solder contact has cooled, the cell is again sealed by a drop of self-leveling adhesive 7 over each solder point 37. The cell is set aside and kept in a horizontal position with the solder points 37 facing upward until the adhesive has spread out and dried over the solder point 37. Any visible conductor elements 44 within the solar cell 2 are covered using a very thin line of black paint 38 to keep their distinctive straight-line pattern from being seen from the front of the leaf 46. Both of the solar cell contact strips 42 and 43 are also covered with black paint 38 to hide their visual signature. Because the conductor elements 44 and the contact strips 42 and 43 do not convert solar energy into power, concealing them behind black paint has no negative effect; however, care must be taken to avoid covering the solar collection areas of the cells 45, otherwise, the power output of the solar cell will be negatively affected. The anode lead 4 is positioned alongside the solar cell 2 and secured with a small amount of self-leveling adhesive 7. This completed unit is then ready for mating to a leaf.

FIG. 4 shows a section through a leaf using an assembly technique in which the solar cell is attached to the bottom of the leaf. In this case, the stem 3 and ribs 40 are partially or completely removed from an existing artificial leaf 1, and the solar cell 2 is mated to the underside of the leaf 47 with the solar collector side of the solar cell 45 facing toward the top face of the leaf 46. (On this type of solar cell, the solar collector side 45 is the side having a black background with silver linear strips at each end and thin silver linear strips that form a grid pattern; the inert side of the cell has no grid pattern and is a solid black or grey color.) The light path is from the top face of the leaf 46 through the leaf material 1 into the collector side of the solar cell 45.

One way to mate the solar cell 2 to the leaf 1 is to attach the solar cell to the bottom side 47 of an unmodified artificial leaf 1. To assemble the device this way, the artificial leaf 1 and solar cell 2 (as prepared as shown in FIG. 3) are positioned on the flat surface of a paint table with the top face of the leaf 46 face down on the table. The solar cell 2 is positioned under the location of the stem 3 and ribs 40 against the bottom side of the leaf 47 so they will help conceal the rectangular shape of the solar cell 2 when they are mated. The two wire leads 4 and 5 from the solar cell 2 are carefully aligned with the solar cell 2 and positioned toward the notch of the leaf 48 for later joining to the stem 3. A thin layer (2-4 mm) of self-leveling adhesive 7 is painted onto the bottom face of the leaf 47 and over the solar cell 2. This adhesive should be mixed using acrylic pigments to match the color of the native leaf it is to imitate. The pigmented self-leveling adhesive 7 is allowed to dry before proceeding. Care must be used to prevent the adhesive 7 from oozing between the collector face of the solar cell 45 and the bottom face of the leaf 47 so as to interfere with the transfer of light into the solar cell 2.

After drying (1 hour nominal time), the solar cell 2 is now securely affixed to the artificial leaf 1, being held in place by the overlying layer of self-leveling adhesive 7.

A second layer of the pigmented self-leveling adhesive 7 is then applied over the bottom face of the leaf 47 and over the solar cell 2 to mask the shape of the solar cell 2. (Additional layers may be added as needed until a smooth surface is achieved on the top of the pigmented adhesive 7.) After the final layer of adhesive 7 is applied, the stem 3 and ribs 40 are applied to the wet adhesive 7 and held in place by direct pressure until they bond to the adhesive surface 7.

A pigmented sealant 8 (same color as used in the pigmented adhesive 7 is applied over the entire back surface of the dried adhesive 7, the ribs 40, and the stem 3. After the sealant 8 has dried, the assembly may be removed from its face-down position on the paint table. A thin (1-2 mm) coating of clear, matte finish ultra-violet protective sealant 6 is painted on the top face of the leaf 46 and allowed to dry. The two wire leads 4 and 5 from the solar cell 2 emerge from the adhesive layer 7 at the notch of the leaf 48 immediately adjacent to the stem 3. These wires 4 and 5 are wrapped around the stem 3 and secured by a drop of self-leveling sealant 7 near the base of the stem 49. The stem 3 and wire leads 4 and 5 are wrapped with florist's tape 39 to secure and camouflage the wire leads. The exterior of the assembly of the stem 3, wire leads 4 and 5, and florist's tape 39 is then painted with pigmented sealant 8 to waterproof and seal the stem. After all components are thoroughly dry, the entire leaf and stem assembly is given a final coating of clear, matte UV protective spray 9.

FIG. 5 shows a section through a leaf using an assembly technique in which the solar cell 2 is embedded between two identical artificial leaves 1 and 50. In this case, the stem 3 and ribs 40 are removed from the front artificial leaf 1 and discarded. The supporting (back) artificial leaf 50 is unaltered and is joined to the front leaf 1 with the solar cell 2 embedded between them. The light path is from the top face of the front leaf 46 through the leaf material 1 into the collector side of the solar cell 45.

To assemble the device using this technique, two identical artificial leaves are selected. The front artificial leaf 1 is separated from its stem 3 and ribs 40, while the supporting artificial leaf 50 is left essentially unmodified. The front leaf 1 and solar cell 2 (prepared with leads 4 and 5 as described earlier) are positioned on the flat surface of a paint table with the top face of the leaf 46 face down on the table. The solar cell 2 is positioned in the middle of the leaf so it will be concealed when the supporting leaf 50 is added. The two wire leads 4 and 5 from the solar cell are carefully aligned with the solar cell 2 and positioned toward the notch of the leaf 48 for later joining to the stem 3. A thin layer (2-3 mm) of self-leveling adhesive 7 is painted onto the bottom face of the front leaf 47 and over the solar cell 2. (Because the leaf is topside down, this bottom face of the leaf 46 is facing upward on the paint table.) The supporting leaf 50 is added while the self-leveling adhesive is wet and is held in place by pressure until the two leaves are bonded. The adhesive 7 is allowed to fully cure before proceeding (4-6 hours). Care must be used to prevent the adhesive 7 from oozing between the collector face of the solar cell 45 and the bottom face of the leaf 47 so as to interfere with the transfer of light into the solar cell 2.

After drying, the solar cell 2 is embedded between the front leaf 1 and the supporting leaf 50. The leaf assembly (leaves 1 and 50 bonded as a unit) may be removed from its face-down position on the paint table. A 1-2 mm coating of clear, matte finish ultra-violet protective sealant 6 is painted on the top face of the leaf 46 and allowed to dry. The two wire leads 4 and 5 from the solar cell 2 emerge from the adhesive layer 7 at the notch of the leaf 48 immediately adjacent to the stem 3. These wires 4 and 5 are wrapped around the stem 3 and secured by a drop of self-leveling sealant 7 near the base of the stem 49. The stem 3 and wire leads 4 and 5 are wrapped with florist's tape 39 to secure and camouflage the wire leads. The exterior of the assembly of the stem 3, wire leads 4 and 5, and florist's tape 39 is then painted with pigmented sealant 8 to waterproof and seal the stem. After all components are thoroughly dry, the entire leaf and stem assembly is given a final coating of clear, matte UV protective spray 9.

FIG. 6 shows an opening in the top face of the leaf 46 revealing the solar cell 2 with its collecting face 45 facing the sunlight through the leaf material 1. This configuration results from either of the two described assembly techniques. Also visible are the two wire leads 4 and 5 that are routed from the solar cell 2 onto the stem 3 where they are wrapped and secured.

FIG. 7 shows the bottom face of the leaf 47 with an opening through the pigmented adhesive 7 and sealant 8 revealing the back side of the solar cell 51. The stem 3 and ribs 40 are also cut away. This figure illustrates a marketing demonstration model of the device that uses a small light emitting diode (LED) 54 affixed to the stem 3. In this case, a 33-ohm resistor 52 is connected to the anode lead 4 from the solar cell 2 and then to the anode lead of the LED 54. The cathode lead 5 of the solar cell 2 is connected to the cathode of the LED 54. To make the LED 54 more viewable in daylight conditions, a small piece of shrink wrap 53 is affixed to the LED and secured by heating the shrink wrap 53 until it is bonded to the LED 54. The LED used in this case was a Radio Shack T−1¾ 5 mm red LED rated at 2.1 v and 20 mA with an output of 3000 mcd. The resistor is a standard ¼ watt 33Ω carbon film resistor. The LED shows to an observer when power is being generated.

FIG. 8 shows the simple circuit of the demonstration leaf device. The cathode lead 5 of the solar cell 2 goes to the cathode of the LED 54. The anode 4 of the solar cell 2 goes to the resistor 52 then to the anode of the LED 54. The resulting circuit produces a visible red light when the leaf is exposed to sunlight.

FIG. 9 shows a hollow foam-filled leaf 30 in which a different technique is used to mate the solar cell 2 to the leaf 30. In this case, the solar cell 2 and its wire leads 4 and 5 are prepared as explained earlier and set aside for mating to the leaf 30. A hollow foam filled leaf 30 is selected that has a realistic appearance and a light-color, low-density surface that will allow plenty of light to pass through to the solar cell 2.

To make the unit, the rounded base of the leaf is opened using a razor blade, exposing the interior foam filler 31. Any type of small, round tool such as a dowel, or long handle of an artist's paint brush is inserted between the foam filler 31 and the plastic surface of the molded leaf 30 to separate the foam from the upper leaf surface, thereby making an opening large enough to hold the solar cell 2. Once the interior space is large enough to hold the solar cell 2, the solar cell 2 is inserted through the opening with the solar collection side of the cell 45 facing the upper surface of the leaf 30. The back side of the solar cell 51 rests on the leaf's foam filler 31. Once the solar cell is fully inserted into the leaf 30, a few drops of self-leveling adhesive 7 are inserted between the back of the solar cell 51 and the foam filler 31. The wire leads 4 and 5 are then wrapped around the stabilizing wire of the leaf 32. The opening in the base of the leaf is then closed and secured with a small amount of the self-leveling adhesive 7. This unit is then left to dry (about 4 hours, typical).

These leaves are then individually joined with other modified and unmodified leaves to fashion a suitable plant in which each modified leaf is capable of producing up to 3 VDC at 25 mA in full sunlight. The leaves may be connected in series or parallel circuits as necessary to construct custom power-producing devices. Small diodes should be used on the anodes 5 of each leaf in a multi-leaf design to prevent reverse current flow, however, they are not needed for a single leaf design as shown. Once the leaf is dry, it is covered with a spray-on coating of UV protective spray 9.

FIG. 10 shows a cross-section of the leaf shown in FIG. 9. This figure shows the solar cell 2 resting on the interior foam filling 31 of the leaf, supported by the internal stabilizing wire 32. The light passes through the thin skin of the leaf 30 to power the solar cell 2 hidden within the artificial leaf.

FIG. 11 shows a common “tin can” that has been modified to be a covert solar collector. There is nothing unusual about the can 33 that would make it appear different from any other trash commonly found in urban settings (for example, in third world cities), except that it must have a white, or very light colored label 34. The light color of the label 34 is important to pass a high amount of solar energy into the solar cells 2 located under the label 34.

To make examples of this kind of sensor, the can 33 is opened and its contents are removed. The top is left on the can to serve as a visual cue that the can is, in fact, empty and to serve as a stabilizing base to keep the solar cells 2 pointed upward toward the sun. The original paper label 34 is carefully removed with a razor blade by making a vertical cut 55 through the label 34 from top to bottom on the part of the can that will lie against the ground with the top of the can opened. The paper label 34 is set aside.

One or two solar cells 2 are prepared as discussed earlier and secured to the can with self-leveling adhesive 7 with the long axis of the solar cells 2 bending around the outside diameter of the can 33. Care must be taken to mount the solar cells 2 directly opposite the point on the can where the vertical cut 55 was made to remove the label. If more than one solar cell 2 is used, they may be wired in parallel or series to meet the requirements of the specific device being powered. After the solar cells 2 have been firmly secured to the can 33 with the self-leveling adhesive 7, they are allowed to dry for about one hour. While the adhesive is drying, the label 34 can be sprayed on both sides with UV protective spray 9 which also acts as a sealant and water barrier to help the label 34 resist both sunlight and rain. The label 34 is set aside to dry after this treatment.

Once the solar cells 2 are mated to the can 33, the wire leads 4 and 5 of each solar cell are connected to provide a simple series or parallel circuit. In this application, the wire leads 4 and 5 may be of 24 to 30 gauge stranded wire, or 22 to 30 gauge magnet wire may be substituted to reduce the visual signature of the leads. The wire leads should be routed to the bottom of the can where the cut 55 was made and secured using self-leveling adhesive 7. Care should be taken to make the wires exit the can at the bottom (unopened end) of the can at the label cut line 55. Diodes between the individual solar cells 2 are not needed in this application because both solar cells typically are in the same level of sunshine at the same time. (Because each solar cell can either produce or consume energy independently, depending upon whether it is in sunlight or shade, rectifying diodes are usually installed between solar cells in an array to prevent reverse current flow. In this application, the can is so small and the two cells are so close together that they both normally receive identical amounts of sunshine.)

If a diode is to be used, a micro 1-amp rectifying diode such as a 1N4003 may be used between the solar cells 2. After the wiring is completed and secured to the can 33, the label 34 is reattached by applying a line of self-leveling adhesive 7 to the body of the can 33 along both sides of the cut line 55. The label 34 is then reattached in its original orientation and held in place by direct pressure until the label is secure.

FIG. 12 shows a common beer bottle 35 that has been modified to be a covert solar collector. There is nothing unusual about the bottle 35 that would make it appear different from any other trash, as for the can discussed above, except that it should be a common brand found in the country of use and should be made of brown glass 34 to hide the solar cell 2 within.

To make the solar collector bottle, the interior of the bottle 35 is washed, cleaned, and dried to remove any liquid residue from the beer. The bottle is oriented so that four small mounds (each ¼ inch nominal diameter) of self-leveling adhesive 7 may be applied to the interior of the bottle using a pipette inserted through the mouth of the bottle 56. The bottle is oriented so that the solar cell 2 will face out through a part of the bottle where there is no label. While the self-leveling adhesive 7 is still wet, a solar cell 2 (prepared as discussed earlier) is inserted through the mouth of the bottle 56 with the solar collection face 45 of the solar cell 2 pointing away from the self-leveling adhesive 7 spots and toward the side of the bottle where there is no label. The back side 51 of the solar cell 2 is seated into the self-leveling adhesive 7 and the bottle is laid horizontal until the self-leveling adhesive 7 is dry (about one hour). The wire leads 4 and 5 are positioned to the side of the mouth of the bottle 56 and the opening is sealed with expanding adhesive foam 36.

FIG. 13 shows a typical deployment scheme in which an “abandoned” piece of trash is actually a solar collector to provide trickle-charge power for a sensor, e.g., a covert sensor, RF device, camera, etc. In the figure a “beer bottle” 35 has its solar cell 2 aligned with its collector face 45 facing the sunlight 28. The solar cell 2 is held in place by self-leveling adhesive 7. The bottle 35 can be partially buried so that the solar cell 2 is facing south at an angle optimized to collect the maximum amount of solar energy 28. In this example, the wire leads 4 and 5 proceed out through the adhesive foam 36 underground to power the covert device. Any array of these types of collectors may be dispersed in a “trash heap” to provide significant amounts of solar power for covert devices with high energy requirements.

FIG. 14 shows a completed external camouflage unit 14 having solar cells in the leaves 10 to provide power for the sensor (not shown) housed within the internal space dedicated for sensor electronics 12. The unit includes a sensor port 11 for a motion detector, optical camera, laser trip-wire, or any other device to be powered. The external camouflage unit 14 is 18″ tall and 6″ in diameter, sized to fit into a soldier's rucksack. The sensor is held within the sensor space 12 and has its own battery that is continually recharged by the power provided from the solar cells embedded within the some of the artificial leaves 10 of the unit. The stabilizing spikes 13 are made of aluminum, and allow a soldier to implant the entire unit 14 quickly and accurately with one hand. These units have been built with the waterproof plastic sensor space 12 inserted into native hardwood that is outfitted with solar collecting leaves 10, a sensor port 11, and stabilizing spikes 13, however, a wide variety of techniques may be employed.

FIG. 15 shows a jungle scene in which the solar-powered sensor array is in operation. These devices can be set up along a trail 57 to detect, record, and report on the movement of people on the trail. Such sensors and arrays of sensors may be employed in a similar way along a waterway, road, runway or other line of communication (not shown, but similar) to covertly detect movement of people, boats, aircraft, or vehicles. Motion detectors in external camouflage units 14 are set up along a trail 57 where they blend in with the natural foliage. Different types of sensors (not shown) may be employed in lieu of a motion detector, such as seismic, acoustic, RF, or other types of devices to collect initial target data. Upon detecting the passage of a target, the motion detectors (or other similar detectors) report to the tree-top relay 16 through a direct RF link 21. An RF link 22 is used to activate the camera and transmitter 15 which is also housed in an external camouflage unit.

Both the motion detectors 14 and the camera unit 15 are powered by batteries that are maintained at full capacity by a solar-power, trickle-charge from the hidden solar cells 2 that collect energy from the sun 28. The camera unit 15 sends its information to the tree-top relay unit 16, which receives the data from the ground sensors 14 and/or 15 through an RF link 21. The relay unit 16 is camouflaged to blend in with the natural foliage and also employs solar cells 2 for long-term charging of its internal batteries. The tree-top relay unit 16 is required in heavy foliage areas, because the relatively weak signal from the sensors is inhibited by the foliage.

Several options may be used to relay data from the sensors 14 and 15 through the relay unit 16; including a cell phone link 17, a satellite link 19 to stationary or transient satellites 18, a direct link 25 to a UAV or aircraft 29, or a direct RF link 20 to the command post 24 using HF or other radio signals. As selected for the specific application, at least one of these signals is forwarded to an off-site command post receiver/processor unit 24 that converts the data into real-time intelligence information. In some cases an uplink transmitter 58 is used to send a coded/encrypted signal 26 through a UAV or aircraft 29. The UAV or aircraft 29 then transmits specific information to a specific sensor via a coded/encrypted downlink 27. An important element in keeping this network working in long-term persistent surveillance is the introduction of covert, solar-charged devices 14, 15, and 16 into the field.

FIG. 16 shows a commercialization scene in which a similar, but less complex communication network is used in a simple construction site security system. The same motion detectors in external camouflage units 14 previously explained in FIG. 15 can be employed in a security network for construction sites or agricultural sites where typical “wired systems” with audible alarms are not practical. The solar power capability of the motion detectors 14 and the camera/transmitter unit 15 housed in an external camouflage unit allow for a solar-powered security system that has no need for AC electrical power. In some cases, these devices camouflaged as plants will be suitable to blend into the environment; however, there are some cases where the sensors must be housed in a typical piece of construction material such as a common 2×4. (See FIG. 17). Solar power is provided through wire leads 4 and 5 from camouflaged solar cells 2 located in typical job site trash (similar to sample configurations previously shown in FIGS. 11 and 12). Common job site components may be used to affix un-camouflaged solar cells 2 to elevated points on a job that are not visible or accessible from the ground, such as rafters and joists that would collect solar energy during daylight hours. The tiny wire leads 4 and 5 would connect the solar cells 2 to the sensors camouflaged as construction material 60 throughout the structure 59. One of the devices included in the camera/transmitter package 15 is a cell phone dialer programmed to call the contractor 61 and/or security/police 62 when motion is detected within or around the structure 59.

FIG. 17 shows how the motion detectors 14 and camera/transmitter units 15 are housed in wood 2×4s with a sensor port 11 and an internal space for sensor electronics 12. The wire leads 4 and 5 are routed to solar cells 2 as previously described. These “2×4s” can be nailed in place to structural members to make them be a part of the structure under construction, to only be removed near the end of a job, if at all.

FIG. 18 shows a way to construct an artificial leaf that can collect solar power. In this case, the solar cell 2 is prepared as described earlier (See FIG. 3) using Teflon-coated 24 to 30-gauge stranded wires 4 and 5. The solar cell 2 is then included in the molding process to include the cell 2 as an integral part of the leaf blank 1. The stem 3 and ribs 40 are molded into the structure as a part of the leaf. After the molding is complete, the wire leads 4 and 5 are routed around the stem and secured as described in Section 1 (See FIG. 1). An artificial leaf constructed in this manner still requires a thin (1-2 mm) coating of pigmented flexible sealant 8 on the back of the leaf to mask the solar cell from visual detection when the leaf has backlighting and the solar cell 2 is visible within the leaf body 1. In addition, it also needs a thin coating (0.5 to 2 mm) of UV absorbing coating 6 on the front face of the leaf and an overall coating of UV protective spray 9.

In some implementations the items referred to by number in the figures could be represented by the following examples.
1. Silk or vinyl artificial leaf (leaf body, also called leaf blank)
2. Solar cell
3. Leaf stem
4. Solar cell anode lead (+)
5. Solar cell cathode lead (−)
6. Clear ultra-violet (UV) protective coating
7. Self-leveling adhesive
8. Pigmented flexible sealant
9. UV protective spray
10. Solar cell within realistic leaf
11. Sensor port
12. Internal space for sensor electronics
13. Stabilizing spikes
14. External camouflage unit (motion detector)
15. External camouflage unit (camera & transmitter)
16. Solar-powered tree-top relay unit
17. Cell phone link
18. Communications satellite
19. Satellite phone link
20. HF radio or other RF Link
21. RF link from camera to relay
22. RF link from motion detectors to camera
23. UAV or aircraft downlink
24. Command post communications receivers
25. Uplink to UAV or aircraft
26. Coded/encrypted uplink
27. Coded/encrypted downlink
28. Sunlight
29. UAV or aircraft
30. Aloe (hollow foam-filled) artificial leaf
31. Internal foam filler
32. Stabilizing wire
33. Empty “tin” can
34. Label on can
35. Empty beer bottle
36. Adhesive foam
37. Solder points
38. Black paint
39. Florist's tape (green)
40. Plastic ribs on artificial leaf
41. Solar cell sealed coating
42. Cathode-end (−) of solar cell
43. Anode-end (+) of solar cell
44. Exposed conductor element
45. Solar cell energy collection area
46. Top face of leaf (faces sun)
47. Bottom of leaf (side away from sun)
48. Notch of leaf
49. Base of stem
50. Secondary artificial leaf
51. Back side of solar cell
52. Resistor (33 ohm)
53. Shrink Wrap
54. High Intensity LED
55. Line of cut on label
56. Mouth of bottle
57. Trail
58. Uplink Transmitter
59. Unattended job site
60. Sensor enclosure camouflaged as construction material
61. Cell phone link to contractor
62. Cell phone link to security/police

A wide variety of other implementations, structures, methods of making and using, and applications are possible for the solar-powered units and sensors and within the scope of the claims.

For example, the covert aspects need not be related to foliage, bottles, cans, or wood, but could be associated with a wide variety of other common objects that are of a size to be deployed easily and are part of environments where surveillance is needed.

1. An apparatus comprising
a solar cell to generate electricity,
a housing for the solar cell, the housing being configured to suit an environment in which the apparatus is to be deployed so that a person who is in the environment and in eye contact with the apparatus is unaware that the apparatus comprises a solar cell, and
a port to couple the generated electricity to a device that senses human activity in the vicinity of the apparatus.

2. The apparatus of claim 1 in which the housing is configured to have the appearance of plant material in the environment.

3. The apparatus of claim 2 in which the housing is configured to have the appearance of a leaf.

4. The apparatus of claim 2 in which the housing is configured to have the appearance of a plant.

5. The apparatus of claim 1 in which the housing is configured to have the appearance of man-made material in the environment.

6. The apparatus of claim 5 in which the housing is configured to have the appearance of trash.

7. The apparatus of claim 6 in which the housing is configured to have the appearance of a discarded bottle or can.

8. The apparatus of claim 1 in which the solar cell comprises a thin-film cell.

9. The apparatus of claim 1 which the solar cell comprises a photovoltaic cell.

10. The apparatus of claim 1 in which the solar cell comprises a flexible cell.

11. The apparatus of claim 1 in which the housing is configured to have the appearance of wood.

12. The apparatus of claim 1 in which the housing comprises wood.

13. The apparatus of claim 12 in which the wood comprises a portion of a structure.

14. The apparatus of claim one in which the solar cell is camouflaged.

15. An apparatus comprising
a set of power units, each of the power units comprising a solar cell, each of the solar cells attached to a housing, each of the housings configured to have an appearance of an environment in which the housing is to be deployed,
a set of sensors powered by the solar cells, and
at least one relay device to be deployed at a distance from the solar cells, the relay device being powered by one of the solar cells and having a relay housing configured to have an appearance of the environment which the relay housing is to be deployed,
the relay device having wireless communication capability to communicate with the sensors and to communicate with a remote data collection device.

16. The apparatus of claim 15 in which each of the power unit housings is configured to have an appearance of plant material.

17. The apparatus of claim 15 in which each of the power unit housings is configured to have the appearance of a leaf.

18. The apparatus of claim 15 in which each of the solar cells comprises of thin-film solar cell.

19. A surveillance system comprising
solar cells camouflaged as artificial plant material,
camouflaged sensors powered by the solar cells, and
wireless communication facilities to send surveillance information determined by the camouflaged sensors to a remote data collector.

20. A surveillance system comprising
solar cells camouflaged as elements of a construction site,
camouflaged sensors powered by the solar cells to detect unauthorized human activity in the vicinity of the construction site, and
a wireless communication facility configured to send an alert when unauthorized human activity is sensed.

21. An apparatus comprising
a device that collects solar energy covertly by being camouflaged relative to the context in which it is deployed.

22. The apparatus of claim 21 in which the camouflaging is relative to a context of at least one of: plant material, mountains, desert, ice, snow, rocks, sand, mud, bricks, signs, banners, construction material, roof material, or an urban landscape.
